(19) United States
(12) Patent Application Publication
(10) Pub. No.: US 2008/0088773 A1
(43) Pub. Date: Apr. 17, 2008

(54) Backlight module with polarizer film, liquid crystal display using same, and method for assembling liquid crystal display

(75) Inventors: Ye-Jun Tang, Shenzhen (CN); Yi Xu, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignees: INNOCOM TECHNOLOGY (SHENZHEN) CO., LTD.; INNOLUX DISPLAY CORP.

(21) Appl. No.: 11/974,847

(22) Filed: Oct. 16, 2007

(30) Foreign Application Priority Data
Oct. 16, 2006 (TW) 95138076

(51) Int. Cl. G02F 1/1335; F21V 7/04; H01L 21/02

(52) U.S. Cl. 349/96; 362/607; 438/30

(57) ABSTRACT

An exemplary liquid crystal display (2) includes a liquid crystal panel (21) and a backlight module (22). The liquid crystal panel includes a first substrate (212), a second substrate (214) opposite to the first substrate, a liquid crystal layer disposed between the substrates, and a first polarizer film (210) provided at an outside of the first substrate. The backlight module includes a light guide plate (222), a light source (230), a second polarizer film (220) and an optical film assembly (224) adjacent to the liquid crystal panel, which has a plurality of optical films. The polarizer film is disposed adjacent to at least one of the optical films. The light guide plate is disposed below the optical film assembly. The light source is positioned for providing light rays to the light guide plate such that the backlight module is capable of providing a planar source of polarized light rays.

### FIELD OF THE INVENTION

The present invention relates to backlight modules, liquid crystal displays using backlight modules, and methods for assembling liquid crystal displays.

### GENERAL BACKGROUND

Because liquid crystal displays (LCDs) have the advantages of portability, low power consumption, and low radiation, they have been widely used in various portable information products such as notebooks, personal digital assistants (PDAs), video cameras, and the like. Furthermore, LCDs are considered by many to have the potential to completely replace CRT (cathode ray tube) monitors and televisions.

Referring to FIG. 5, a typical LCD 1 includes a liquid crystal panel 11, and a backlight module 12 adjacent to the liquid crystal panel 11. The liquid crystal panel 11 includes a first substrate 112, a second substrate 114 parallel to the first substrate 112, and a liquid crystal layer (not shown) interposed between the first and second substrates 112, 114. A first and a second polarizer films 110, 115 are provided at two outer sides of the first and second substrates 112, 114, respectively. The first and second polarizer films 110, 115 have a similar structure.

FIG. 6 shows the second polarizer film 115 prior to assembly of the liquid crystal panel 11. The second polarizer film 115 includes a release layer 116, a polarization main body 117, and a protection film 118, arranged in that order from top to bottom. The protection film 118 is highly transparent and waterproof so as to protect the polarization main body 117. The release layer 116 is used to keep a contact surface of the polarization main body 117 clean and sticky. In assembly of the liquid crystal panel 11, the release layer 116 is peeled off, and the polarization main body 117 is adheringly attached to the second substrate 114.

The backlight module 12 includes an optical film assembly 124, a light guide plate 122, and a frame 123, arranged generally in that order from top to bottom. When the backlight module 12 is assembled, the optical film assembly 124 and the light guide plate 122 are received in the frame 123. The optical film assembly 124 includes an upper diffusing film 125, an upper brightness enhancement film (BEF) 126, a lower BEF 127, and a lower diffusing film 128, arranged in that order from top to bottom. The light guide plate 121 includes a light emitting surface 122 adjacent to the lower diffusing film 128.

When the first and second polarizer films 110, 115 are attached onto the first and second substrates 112, 114 during assembly of the liquid crystal panel 11, defects may occur. In particular, a display area of the liquid crystal panel 11 may have air bubbles. As a result, the quality of images displayed by the liquid crystal panel 11 may be impaired. Further, with the passing of time, the first and second polarizer films 110, 115 may peel off from the first and second substrates 112, 114.

Even when the LCD 1 is manufactured to the highest standards, it is difficult to completely eliminate the formation of bubbles when the polarizer films 110, 115 are attached onto the first and second substrates 112, 114. In addition, the protection films 118 of the polarizer films 110, 115 may have slight physical distortions, which render the polarizer films 110, 115 more liable to be accidentally scraped. Furthermore, the polarizer films 110, 115 are liable to partially detach from the first and second substrates 112, 114 with the passing of time. This can cause or accelerate ageing and decay of the polarizer films 110, 115.

What is needed is a liquid crystal display that can overcome the above-described deficiencies. What is also needed is a method for assembling such liquid crystal display.

### SUMMARY

In one preferred embodiment, a liquid crystal display includes a liquid crystal panel and a backlight module. The liquid crystal panel includes a first substrate, a second substrate opposite to the first substrate, a liquid crystal layer disposed between the substrates, and a first polarizer film provided at an outside of the first substrate. The backlight module includes a light guide plate, a light source, a second polarizer film and an optical film assembly. The optical film assembly includes a plurality of optical films. The polarizer film is disposed adjacent to at least one of the optical films. The light guide plate is disposed below the optical film assembly. The optical film assembly is disposed adjacent to the liquid crystal panel. The light source is positioned for providing light rays to the light guide plate such that the backlight module is capable of providing a planar source of polarized light rays.

Other aspects, novel features and advantages will become more apparent from the following detailed description when taken in conjunction with the accompanying drawings.

### BRIEF DESCRIPTION OF THE DRAWINGS

The components in the drawings are not necessarily drawn to scale, the emphasis instead being placed upon clearly illustrating the principles of at least one embodiment of the present invention. In the drawings, like reference numerals designate corresponding parts throughout various views, and all the views are schematic.

FIG. 1 is an exploded, isometric view of a liquid crystal display according to a first embodiment of the present invention, the liquid crystal display including a backlight module, the backlight module including a second polarizer film.

FIG. 2 is a side plan view of the second polarizer film of FIG. 1.

FIG. 3 is an assembled view of the liquid crystal display of FIG. 1.

FIG. 4 is an exploded, isometric view of a liquid crystal display according to a second embodiment of the present invention.

FIG. 5 is an exploded, isometric view of a conventional liquid crystal display.

FIG. 6 is a side plan view of a second polarizer film of the liquid crystal display of FIG. 5.

### DETAILED DESCRIPTION OF PREFERRED EMBODIMENTS

Reference will now be made to the drawings to describe preferred and exemplary embodiments of the present invention in detail.

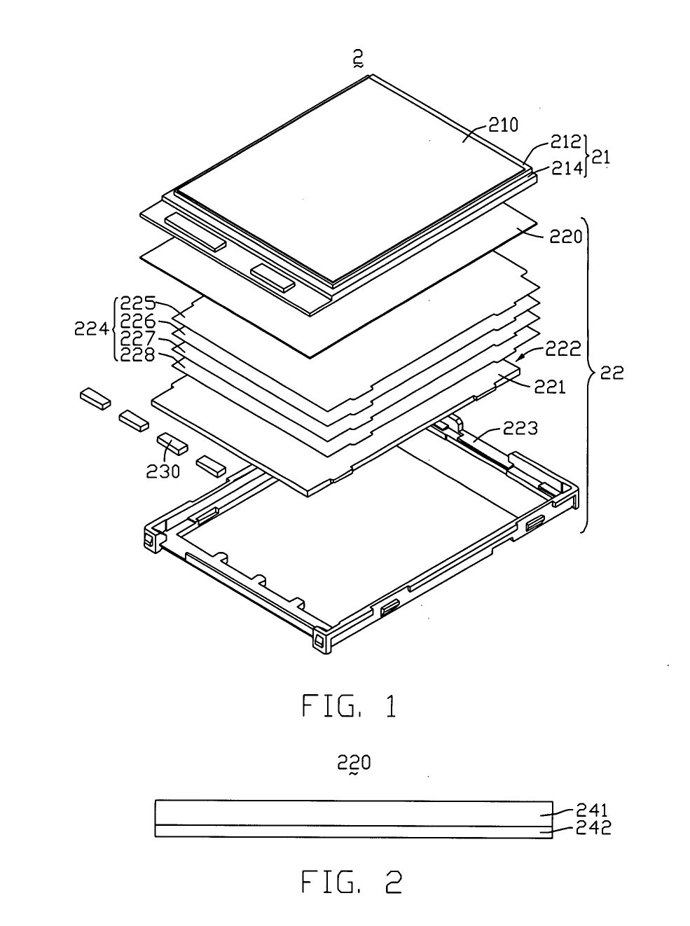

Referring to FIG. 1, a liquid crystal display 2 according to a first embodiment of the present invention is shown. The liquid crystal display 2 includes a liquid crystal panel 21 and a backlight module 22. The liquid crystal panel 21 includes a first substrate 212, a second substrate 214 parallel to the first substrate 212, a liquid crystal layer (not shown) interposed between the first and second substrates 212, 214, and a first polarizer film 210 provided at an outside of the first substrate 212. The first polarizer film 210 has a first polarizing direction.

The backlight module 22 includes a second polarizer film 220, an optical film assembly 224, a light guide plate 222 adjacent to the optical film assembly 224, a plurality of light sources 230, and a frame 223. The second polarizer film 220, the optical film assembly 224, and the light guide plate 222 are arranged in that order from top to bottom. The light sources 230 are disposed adjacent to a side edge of the light guide plate 222, so as to provide light rays to the light guide plate 222. When the backlight module 22 is assembled, the second polarizer film 220, the optical film assembly 224, the light guide plate 222 and the light sources 230 are received in the frame 223. The second polarizer film 220 has a second polarizing direction perpendicular to the first polarizing direction.

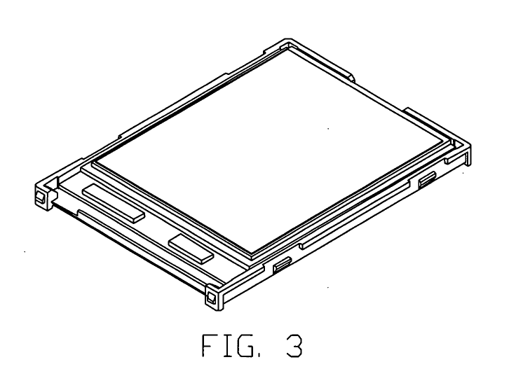

Referring also to FIG. 2, the second polarizer film 220 includes a polarization main body 241 and a protection film 242. The polarization main body 241 is adjacent to the second substrate 214. The protection film 242 is transparent and waterproof for protecting the polarization main body 241.

The optical film assembly 224 includes an upper diffusing film 225, an upper BEF 226, a lower BEF 227, and a lower diffusing film 228, arranged in that order from top to bottom.

The light guide plate 222 includes a light emitting surface 221 adjacent to the lower diffusing film 228.

Because the backlight module 22 includes the second polarizer film 220, light rays which pass through the second polarizer film 220 are polarized. Therefore the backlight module can provide polarized light rays to the liquid crystal panel 21.

FIG. 3 shows the liquid crystal display 2 fully assembled. Detailed steps of assembly of the liquid crystal display 2 are as follows:

The first and second substrates 212, 214 are provided.

The first and second substrates 212, 214 are attached together, with the liquid crystal layer sealed between the two substrates 212, 214.

The first polarizer film 210 is adhered onto the outside of the first substrate 212. Thus, the liquid crystal panel 21 is assembled.

The optical film assembly 224, the light guide plate 222, the light sources 230, and the frame 223 are provided. The optical film assembly 224 includes the upper diffusing film 225, the upper BEF 226, the lower BEF 227, and the lower diffusing film 228, which are arranged in that order from top to bottom.

The light guide plate 222 is received in and fixed to the frame 223, and the light sources 230 are received in the frame 223 and fixed in position adjacent to the side edge of the light guide plate 222. The optical film assembly 224 is placed on the light guide plate 222.

The second polarizer film 220 is positioned on top of the upper diffusing film 225. Thus, the backlight module 22 is assembled.

The liquid crystal panel 21 and the backlight module 22 are fixed together. In particular, the liquid crystal panel 21 can be press-fitted onto the backlight module 22. Further or alternatively, a top bezel (not shown) of the liquid crystal display 2 can be snap-fitted onto the frame 223, such that the top bezel and the frame 223 cooperatively hold the liquid crystal panel 21 therebetween. Thereby, the liquid crystal panel 21 is fixed in the frame 223. Thus, the second polarizer film 220 is securely sandwiched between the liquid crystal panel 21 and the optical film assembly 224.

Because the second polarizer film 220 is provided in the backlight module 22, the second polarizer film 220 need only include the polarization main body 241 and the protection film 242. That is, there is no need to attach the second polarizer film 220 to the second substrate 214. Unlike in a conventional liquid crystal display, there are no problems associated with detaching or peeling of the second polarizer film 220 from the liquid crystal panel 21. Therefore the possibility of defects occurring in the liquid crystal panel 21 can be reduced. In particular, no air bubbles are formed.

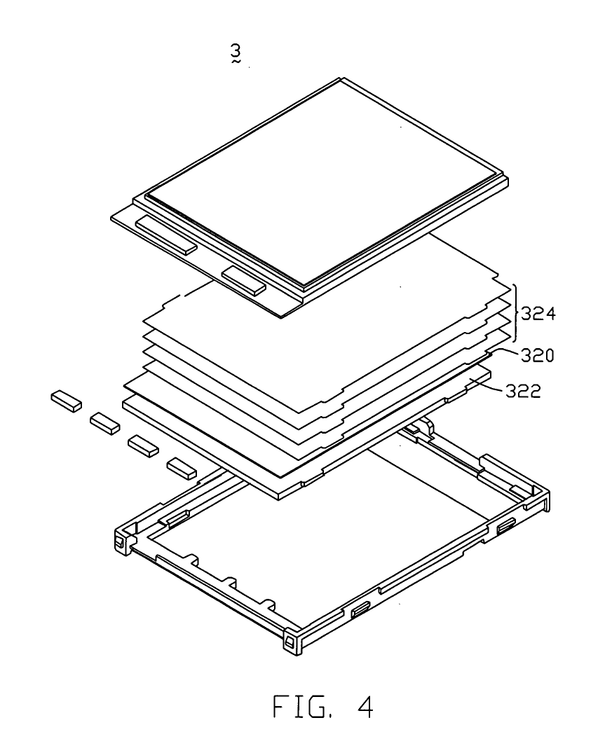

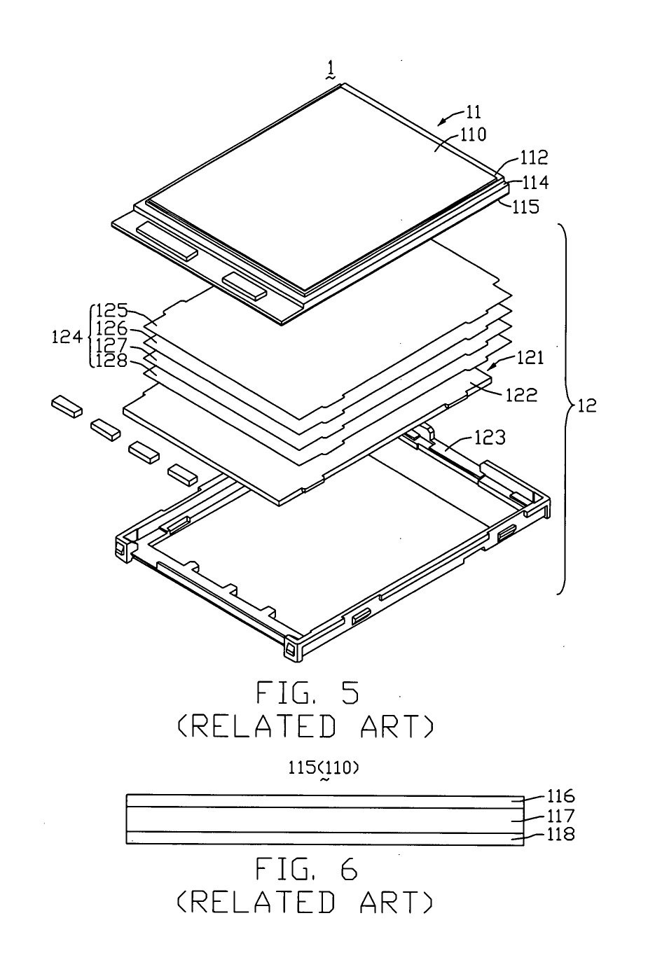

Referring also to FIG. 4, a liquid crystal display 3 according to a second embodiment of the present invention is shown. The liquid crystal display 3 is similar to the liquid crystal display 2 of the first embodiment. However, in the liquid crystal display 3, a second polarizer film 320 is provided between an optical film assembly 324 and a light guide plate 322. The liquid crystal display 3 can achieve advantages similar to those described above in relation to the liquid crystal display 2.

Further or alternative embodiments may include the following. In one example, the second polarizer film 320 can instead be disposed between any two selected adjacent films of the optical film assembly 324.

It is believed that the present embodiments and their advantages will be understood from the foregoing description, and it will be apparent that various changes may be made thereto without departing from the spirit or scope of the invention or sacrificing all of its material advantages, the examples hereinbefore described merely being preferred or exemplary embodiments of the invention.

What is claimed is:

1. A backlight module comprising:
an optical film assembly comprising a plurality of optical films;
a polarizer film disposed adjacent at least one of the optical films;
a light guide plate below the optical film assembly; and
a light source positioned for providing light rays to the light guide plate such that the backlight module is capable of providing a planar source of polarized light rays.

2. The backlight module in claim 1, further comprising a frame, wherein the optical film assembly, the polarizer film, the light guide plate and the light source are received in the frame.

3. The backlight module in claim 1, wherein the optical films comprise an upper diffusing film, an upper brightness enhancement film beneath the upper diffusing film, a lower brightness enhancement film beneath the upper brightness enhancement film, and a lower diffusing film beneath the lower brightness enhancement film.

4. The backlight module in claim 3, wherein the polarizer film is disposed between the upper diffusing film and the upper brightness enhancement film.

5. The backlight module in claim 3, wherein the polarizer film is disposed between the upper brightness enhancement film and the lower brightness enhancement film.

6. The backlight module in claim 3, wherein the polarizer film is disposed between the lower brightness enhancement film and the lower diffusing film.

7. The backlight module in claim 1, wherein the polarizer film comprises a polarization main body and a protection film provided on the polarization main body.

8. A liquid crystal display comprising:
a liquid crystal panel comprising:
a first substrate;
a second substrate; and
a liquid crystal layer between the first substrate and the second substrate;
a backlight module adjacent to the liquid crystal panel, the backlight module comprising:
an optical film assembly comprising a plurality of optical films;
a polarizer film disposed adjacent at least one of the optical films;
a light guide plate below the optical film assembly; and
a light source positioned for providing light rays to the light guide plate such that the backlight module is capable of providing a planar source of polarized light rays.

9. The liquid crystal display in claim 8, further comprising a polarizer film provided on the first substrate, the backlight module being disposed adjacent to the second substrate, polarizing directions of the two polarizer being perpendicular.

10. The liquid crystal display in claim 8, wherein the backlight module further comprises a frame, the optical film assembly, the light guide plate and the polarizer film being received in the frame.

11. The liquid crystal display in claim 8, wherein the optical films are an upper diffusing film, an upper brightness enhancement film beneath the upper diffusing film, a lower brightness enhancement film beneath the upper brightness enhancement film and a lower diffusing film beneath the lower brightness enhancement film.

12. The liquid crystal display in claim 9, further comprising a polarizer film arranged on the first substrate.

13. A method for assembling a liquid crystal display, the method comprising:
providing a liquid crystal panel;
providing a backlight module comprising a polarizer film; and
attaching the liquid crystal panel to the backlight module.

14. The method in claim 13, wherein providing a liquid crystal panel comprises:
providing a first substrate and a second substrate; and
attaching the first and the second substrates together.

15. The method in claim 14, wherein providing a liquid crystal panel further comprises: providing a polarizer film, and attaching the polarizer film to an outside of the first substrate.

16. The method in claim 13, wherein providing a backlight module comprising a polarizer film comprises:
providing an optical film assembly and a polarizer film; and
disposing the polarizer film adjacent to or within the optical film assembly.

17. The method in claim 16, wherein providing a backlight module comprising a polarizer film further comprises:
providing a light guide plate and a frame;
disposing the light guide plate in the frame; and
placing the optical film assembly on the light guide plate.

18. The method in claim 13, wherein when the liquid crystal panel is attached to the backlight module, the optical film assembly is adjacent to the liquid crystal panel.
